(19) United States
(12) Patent Application Publication
(10) Pub. No.: US 2024/0297631 A1
(43) Pub. Date: Sep. 5, 2024

(54) CIRCUIT DEVICE

(71) Applicant: Murata Manufacturing Co., Ltd., Nagaokakyo-shi (JP)

(72) Inventor: Atsushi TOUJO, Nagaokakyo-shi (JP)

(21) Appl. No.: 18/663,139

(22) Filed: May 14, 2024

Related U.S. Application Data
(63) Continuation of application No. PCT/JP2022/041328, filed on Nov. 7, 2022.

(30) Foreign Application Priority Data
Nov. 22, 2021 (JP) 2021-189637

(51) Int. Cl. H03H 7/01; H01F 27/06; H01F 27/29

(52) U.S. Cl. CPC H03H 7/0115; H01F 27/06; H01F 27/29; H03H 7/1775; H01F 2027/065

(57) ABSTRACT

A circuit device includes a substrate and a coil component including a first coil and a second coil that are magnetically coupled to each other. A wiring pattern includes a first wiring line, a second wiring line, a third wiring line on which capacitors are mounted in series, and a fourth wiring line that electrically connects the first wiring line or the second wiring line to a ground electrode. A distance between a first current path on which a current flows from the coil component to a ground electrode via the third wiring line and a second current path on which a current flows from the first wiring line or the second wiring line to the ground electrode via the fourth wiring line on which capacitors are mounted at an electrode is not constant.

### CROSS REFERENCE TO RELATED APPLICATIONS

This application claims the benefit of priority to Japanese Patent Application No. 2021-189637 filed on Nov. 22, 2021 and is a Continuation Application of PCT Application No. PCT/JP2022/041328 filed on Nov. 7, 2022. The entire contents of each application are hereby incorporated herein by reference.

### BACKGROUND OF THE INVENTION

### 1. Field of the Invention

The present disclosure relates to circuit devices in which coil components are mounted.

### 2. Description of the Related Art

Noise countermeasures using a filter circuit are included in electronic devices. A filter circuit used for noise countermeasures, such as an EMI (electro-magnetic interference) removal filter, passes a necessary component of a current flowing through a conductor and eliminates an unnecessary component. Such a filter circuit includes a capacitor that is a capacitance element. It is thus known that a noise suppression effect is reduced by an equivalent series inductance (ESL) that is a parasitic inductance of the capacitor.

A technique is known for canceling out an equivalent series inductance ESL of a capacitor by a negative inductance generated by magnetic coupling between two coils and achieving the noise reduction effect of a filter circuit in a wider band (for example, Japanese Unexamined Patent Application Publication No. 2001-160728).

In the case where a circuit using a capacitor is installed in a vehicle, a redundant circuit configuration in which two capacitors are connected in series is provided in some cases for preventing the circuit from being short-circuited even if the capacitor included in the circuit fails. Accordingly, in the case where a filter circuit is installed in a vehicle, a redundant circuit configuration needs to be also applied to the filter circuit (for example, Japanese Unexamined Patent Application Publication No. 2004-022561).

### SUMMARY OF THE INVENTION

However, in the case where the parasitic inductance of a capacitor is canceled out by a negative inductance generated by magnetic coupling between two coils when there is a wiring line of another capacitor other than the capacitor that generates the parasitic inductance, the parasitic inductance may change under the influence of the wiring line. Furthermore, it is difficult to understand in advance how noise occurs and it is therefore difficult to specify the parasitic inductance of a capacitor under the conditions that the number of capacitors mounted in a filter circuit and the arrangement of the capacitors are determined in advance.

Example embodiments of the present invention provide circuit devices with each of which changes in parasitic inductance of a capacitor can be reduced or prevented.

A circuit device according to an example embodiment of the present disclosure includes a substrate on which a wiring pattern is provided and a coil component mounted on the substrate. The coil component includes a first coil and a second coil that are magnetically coupled to each other. A first end of the first coil is connected to an input terminal, a second end of the first coil and a first end of the second coil are connected to an intermediate terminal, and a second end of the second coil is connected to an output terminal. The wiring pattern includes a first wiring line connected to the input terminal, a second wiring line connected to the output terminal, a third wiring line on which at least one or more capacitors are mounted in series and which electrically connects the intermediate terminal and a ground electrode, and a fourth wiring line on which an electrode provided to mount at least one or more capacitors in series is provided and which electrically connects the first wiring line or the second wiring line to a ground electrode. A distance between a first current path on which a current flows from the coil component to a ground electrode via the third wiring line and a second current path on which a current flows from the first wiring line or the second wiring line to a ground electrode via the fourth wiring line on which a capacitor is mounted at an electrode is not constant.

According to an example embodiment of the present disclosure, a structure is provided where a third wiring line and a fourth wiring line are not parallel to each other. Accordingly, the change in the parasitic inductance of a capacitor can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a circuit device according to a first example embodiment of the present invention.

FIG. 2 is a circuit diagram of the circuit device according to the first example embodiment of the present invention.

FIG. 3 is a perspective view of a coil component according to the first example embodiment of the present invention.

FIG. 4 is a graph describing the change in the parasitic inductance of the circuit device according to the first example embodiment of the present invention.

FIG. 5 is a plan view of a circuit device according to a comparative example.

FIG. 6 is a plan view of the circuit device according to the first example embodiment of the present invention when the circuit device does not include some of capacitors.

FIG. 7 is a plan view of a circuit device according to a first modification of the first example embodiment of the present invention

FIG. 8 is a plan view of a circuit device according to a second modification of the first example embodiment of the present invention.

FIGS. 9A and 9B are plan views of a circuit device according to a third modification of the first example embodiment of the present invention.

FIGS. 10A and 10B are plan views of a circuit device according to a fourth modification of the first example embodiment of the present invention.

FIG. 11 is a plan view of a circuit device according to a second example embodiment of the present invention.

FIG. 12 is a plan view of a circuit device according to a first modification of the second example embodiment of the present invention.

FIG. 13 is a plan view of a circuit device according to a second modification of the second example embodiment of the present invention.

### DETAILED DESCRIPTION OF THE EXAMPLE EMBODIMENTS

### First Example Embodiment

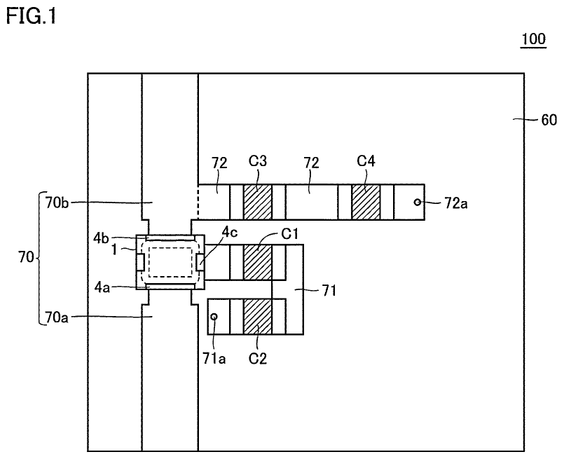

A circuit device according to the first example embodiment will be described below. FIG. 1 is a plan view of a circuit device 100 according to the first example embodiment. The circuit device 100 is a filter circuit used for, for example, noise countermeasures taken for a power supply line 70 and includes a coil component 1 including two coils that are magnetically coupled to each other for the cancellation of the parasitic inductance of capacitors C1 and C2. The circuit device 100 is not limited to a filter circuit used for noise countermeasures taken for the power supply line 70 and may be a filter circuit used for noise countermeasures taken for, for example, another signal line.

In the circuit device 100, the wiring pattern of the power supply line 70 is provided on the surface of a substrate 60 and the coil component 1 is mounted in series to the power supply line 70. The power supply line 70 includes a first wiring line 70a connected to an input terminal 4a of the coil component 1 and a second wiring line 70b connected to an output terminal 4b of the coil component 1.

The substrate 60 is provided by laminating a plurality of insulating layers and is made of, for example, low-temperature co-fired ceramics or a glass epoxy resin. Wiring patterns, such as the first wiring line 70a and the second wiring line 70b, the coil component 1, electrode patterns provided to mount components, such as the capacitors C1 and C2 and capacitors C3 and C4, are formed on the surface of the substrate 60 and are each made of a metal material, such as Cu, Ag, or Al that is generally used as an electrode material.

In the circuit device 100, the two capacitors C1 and C2 are connected in series to an intermediate terminal 4c of the coil component 1. On the substrate 60, the wiring pattern of a third wiring line 71 is provided as a wiring line to mount the capacitors C1 and C2. The third wiring line 71 electrically connects the intermediate terminal 4c between the two coils included in the coil component 1 and a ground electrode 71a with the capacitors C1 and C2 mounted thereon. In the circuit device 100, the two capacitors C3 and C4 are connected in series between the second wiring line 70b near the coil component 1 and a ground electrode 72a. On the substrate 60, the wiring pattern of a fourth wiring line 72 is provided as a wiring line to mount the capacitors C3 and C4. The fourth wiring line 72 electrically connects the second wiring line 70b and the ground electrode 72a with the capacitors C3 and C4 mounted thereon. The fourth wiring line 72 may be provided on the first wiring line 70a instead of the second wiring line 70b. A ground electrode is an electrode electrically connected to a ground potential and is provided of, for example, a conductive via electrically connected to a ground potential placed in the inner layer of the substrate 60. The third wiring line 71 and the fourth wiring line 72 are wiring lines to provide the electric connection from a coil component, the first wiring line 70a, and the second wiring line 70b to the ground electrodes 71a and 72a via capacitors and are each represented as a group of a plurality of wiring lines.

The fourth wiring line 72 linearly extends from the second wiring line 70b to the ground electrode 72a as illustrated in FIG. 1 and has a linear shape. However, the third wiring line 71 has a U-shape bending twice from the intermediate terminal 4c and reaching the ground electrode 71a. Thus, by giving the third wiring line 71 a U-shape instead of a linear shape that is the same as the shape of the fourth wiring line 72, the change in the parasitic inductance of the capacitors C1 and C2 can be reduced or prevented as will be described below.

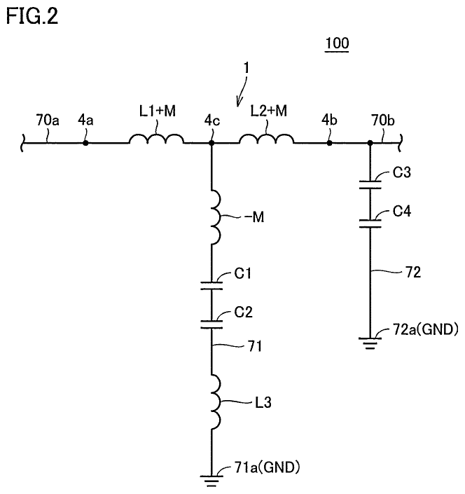

FIG. 2 is a circuit diagram of the circuit device 100 according to the first example embodiment. Specifically, the circuit device 100 is an EMI rejection filter and is a third-order T-type LC filter circuit. The configuration of the circuit device 100 will be described as being a third-order T-type LC filter circuit in the present disclosure, but a similar configuration may also be applied to a fifth-order T-type LC filter circuit or a higher-order T-type LC filter circuit. The circuit device 100 includes the coil component 1 and the capacitors C1 to C4 as illustrated in FIG. 2.

The coil component 1 includes the input terminal 4a, the output terminal 4b, the intermediate terminal 4c, a coil L1 (first coil), and a coil L2 (second coil).

The capacitors C1 and C2 are connected in series between the input terminal 4a and the ground electrode 71a as illustrated in FIG. 2. Any one of the capacitors C1 and C2 may be provided, but a redundant circuit configuration in which the two capacitors are connected in series is used assuming that, for example, they are mounted in a vehicle. The capacitors C3 and C4 are similarly connected in series between the second wiring line 70b and the ground electrode 72a.

Each of the capacitors C1 to C4 may be not only a multilayer ceramic capacitor made of BaTiO₃ (barium titanate) as a main component but also a multilayer ceramic capacitor made of another material as a main component or a capacitor of another type, such as an aluminum electrolytic capacitor, which is not a multilayer ceramic capacitor.

The capacitors C1 and C2 connected to the coil component 1 includes an inductor L3 as a parasitic inductance (equivalent series inductance (ESL)). Accordingly, the circuit device 100 is equivalent to a circuit configuration in which the inductor L3 is connected in series to the capacitors C1 and C2 as illustrated in FIG. 2.

The coils L1 and L2 are connected to the intermediate terminal 4c as well as the capacitors C1 and C2. The coils L1 and L2 are magnetically coupled to each other and generate a negative inductance component (mutual inductance M). With the negative inductance component, the parasitic inductance (the inductor L3) of the capacitors C1 and C2 can be canceled out, and an apparent inductance component of the capacitors C1 and C2 can be reduced. FIG. 2 illustrates an equivalent circuit in which the mutual inductance M (−M) for canceling out the inductor L3 is connected in series to the capacitors C1 and C2 and the mutual inductance M (+M) is added to each of the coils L1 and L2.

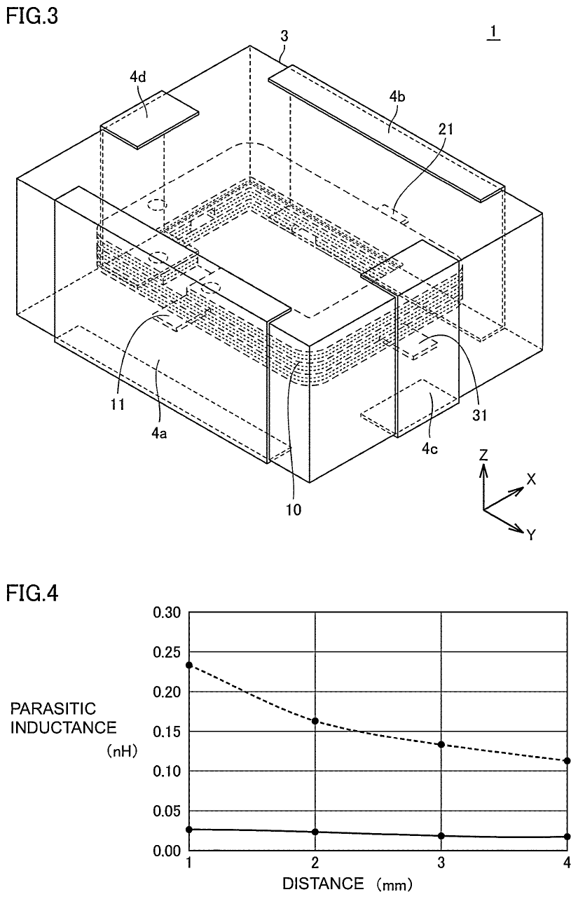

The circuit device 100 including the capacitors C1 and C2 and the coils L1 and L2 can improve a noise reduction effect in a high frequency band by canceling out the parasitic inductance of the capacitors C1 and C2 by a negative inductance component generated by the mutual inductance M between the coils L1 and L2. The coil component 1 includes the coil L1 (the first coil) and the coil L2 (the second coil) that are transformer coils and are provided in a laminate body such that respective coil surfaces face each other in a lamination direction, and is mounted such that the respective coil surfaces are parallel or substantially parallel to the surface of the substrate 60. The configuration of the coil component 1 will be described with reference to a drawing. FIG. 3 is a perspective view of the coil component 1 according to the first example embodiment. In FIG. 3, a short-side direction of the coil component 1 is an X direction, a long-side direction of the coil component 1 is a Y direction, and a height direction of the coil component 1 is a Z direction. A lamination direction of a substrate is the Z direction, and the direction of the arrow of the Z direction represents an upper layer direction.

As illustrated in FIG. 3, the coil component 1 includes a ceramic laminate body 3 (ceramic body) in which a plurality of substrates (ceramic green sheets) where coil wiring lines are formed are laminated. The laminate body 3 has a pair of main surfaces facing each other and side surfaces connecting the main surfaces. A plurality of wiring patterns 10 of the coils L1 and L2 are laminated from the bottom such that they are parallel or substantially parallel to the main surfaces of the laminate body 3.

The side surfaces of the laminate body 3 include a first side surface (a side surface on which the input terminal 4a (a first external electrode) is provided) and a second side surface (a side surface on which the output terminal 4b (a second external electrode) is provided) on the long side and a third side surface (a side surface on which the intermediate terminal 4c (a third external electrode) is provided) and a fourth side surface (a side surface on which a terminal 4d is provided) on the short side.

In the coil component 1, the multiple wiring patterns 10 of the coils L1 and L2 are placed inside the laminate body 3. A portion of the multiple wiring patterns 10 defines the coil L1, and the remaining portion of them forms the coil L2. That is, the multiple wiring patterns 10 have a common portion of the coils L1 and L2, and the variations of magnetic coupling between the coils L1 and L2 can therefore be reduced or prevented.

An end portion 11 of the wiring pattern 10 in the uppermost layer, which is one of the multiple wiring patterns 10, is electrically connected to the input terminal 4a. An end portion 21 of the wiring pattern 10 in the lowermost layer, which is one of the multiple wiring patterns 10, is electrically connected to the output terminal 4b. An end portion 31 of the wiring pattern 10 in the middle layer, which is one of the multiple wiring patterns 10, is electrically connected to the intermediate terminal 4c. In the coil component 1 having the configuration illustrated in FIG. 3, the mutual inductance M between the coils L1 and L2 is determined as a constant value.

Next, the change in a parasitic inductance in the circuit device 100 will be described. FIG. 4 is a graph describing the change in a parasitic inductance in the circuit device 100 according to the first example embodiment. Referring to FIG. 4, the horizontal axis represents the distance between wiring lines and the vertical axis represents the amount of change in a parasitic inductance. FIG. 5 is a plan view of a circuit device 300 according to a comparative example. In the circuit device 300 illustrated in FIG. 5, the same reference numeral is used to represent the same configuration as the circuit device 100 illustrated in FIG. 1 and the detailed description thereof will not be repeated.

As illustrated in FIG. 5, in the circuit device 300 according to a comparative example, a third wiring line 71A provided to mount the capacitors C1 and C2 does not have a U-shape but a linear shape linearly extending from the intermediate terminal 4c to the ground electrode 71a. Accordingly, the third wiring line 71A and the fourth wiring line 72 are parallel or substantially parallel to each other on the substrate 60. Since the direction of a current flowing through the third wiring line 71A and the direction of a current flowing through the fourth wiring line 72 are always the same when the third wiring line 71A and the fourth wiring line 72 are parallel or substantially parallel to each other, the degree of magnetic coupling between the third wiring line 71A and the fourth wiring line 72 increases in this arrangement. Although the two wiring lines are parallel or substantially parallel to each other on the substrate in the present disclosure, the two wiring lines do not necessarily have to be geometrically parallel to each other at least on condition that the directions of currents flowing through the wiring lines are parallel or substantially parallel to each other.

The increase in the degree of magnetic coupling between the third wiring line 71A and the fourth wiring line 72 leads to the increase in the parasitic inductance of the capacitors C1 and C2, and the parasitic inductance cannot therefore be sufficiently canceled out by the mutual inductance M of the coil component 1 in the circuit device 300.

On the other hand, the third wiring line 71 provided to mount the capacitors C1 and C2 is U-shaped in the circuit device 100 as illustrated in FIG. 1. Accordingly, a current flowing through the capacitor C1 and a current flowing through the capacitor C2 are opposite in direction, and the degree of magnetic coupling between a portion where the capacitor C1 is mounted and a portion where the capacitor C2 is mounted decreases. Here, a current path from the coil component 1 to the ground electrode 71a via the third wiring line 71 on which the capacitors C1 and C2 are mounted is referred to as a first current path. The first current path includes paths where current flow directions are opposite.

Since the degree of magnetic coupling between the portion where the capacitor C1 is mounted and the portion where the capacitor C2 is mounted decreases, the degree of magnetic coupling between the third wiring line 71 and the fourth wiring line 72 also decreases. That is, by making the third wiring line 71 U-shaped, the third wiring line 71 is less susceptible to the magnetic coupling with the fourth wiring line 72 and the amount of change in the parasitic inductance of the capacitors C1 and C2 can be reduced.

The shape of the third wiring line 71 is a U-shape in which the capacitor C1 is mounted on one of the long sides and the capacitor C2 is mounted on the other one of them as illustrated in FIG. 1, but is not limited to the shape and may be any shape including a portion not parallel to the fourth wiring line 72. By causing the third wiring line 71 to include a portion not parallel to the fourth wiring line 72, the effect of magnetic coupling with the fourth wiring line 72 upon the third wiring line 71 can be reduced. Here, a current path from the second wiring line 70b to the ground electrode 72a via the fourth wiring line 72 on which the capacitors C3 and C4 are mounted is referred to as a second current path. The third wiring line 71 including a portion not parallel to the fourth wiring line 72 means that the distance between the first current path and the second current path is not constant.

On the U-shaped third wiring line 71, the capacitors C1 and C2 are mounted parallel or substantially parallel to each other. Accordingly, the capacitors C1 and C2 can be mounted in the same direction and be easily mounted on the substrate 60. The first current path (the path of the third wiring line 71) connected to the coil component 1 and the second current path (the path of the fourth wiring line 72) connected to the second wiring line 70b are parallel or substantially parallel to each other. However, the first current path (the path of the third wiring line 71) bends at right angles in the middle. The angle at which the path bends does not necessarily have to be a right angle.

The strength of the magnetic coupling between the third wiring line and the fourth wiring line depends on the distance between these wiring lines. In the graph illustrated in FIG. 4, the amount of change in the parasitic inductance of the capacitors C1 and C2 at the distance (shortest distance) between the U-shaped third wiring line 71 and the fourth wiring line 72 in the circuit device 100 is represented by a solid line and the amount of change in the parasitic inductance of the capacitors C1 and C2 at the distance between the linear third wiring line 71A and the fourth wiring line 72 in the circuit device 300 is represented by a broken line.

In the case where the distance between the linear third wiring line 71A and the fourth wiring line 72 is short (e.g., approximately 1 mm) in the circuit device 300, the parasitic inductance of the capacitors C1 and C2 is higher than that in the configuration of a circuit device not including the fourth wiring line 72 by approximately 0.23 nH, for example. Also in the case where the distance between the third wiring line 71A and the fourth wiring line 72 is approximately 4 mm, the parasitic inductance of the capacitors C1 and C2 is higher than that in the configuration by approximately 0.11 nH, for example.

In the case where the distance between the U-shaped third wiring line 71 and the fourth wiring line 72 is short (e.g., approximately 1 mm) in the circuit device 100, the parasitic inductance of the capacitors C1 and C2 changes only by approximately 0.03 nH as compared with the configuration of a circuit device not including the fourth wiring line 72, for example. Also in the case where the distance between the third wiring line 71 and the fourth wiring line 72 is approximately 4 mm, the parasitic inductance of the capacitors C1 and C2 changes only by approximately 0.02 nH, for example.

As is apparent from FIG. 4, the U-shaped third wiring line 71 is less susceptible to the magnetic coupling with the fourth wiring line 72 even when the fourth wiring line 72 is provided near the third wiring line 71. Specifically, even when the wiring line width of the third wiring line 71 or the fourth wiring line 72 is approximately 1 mm and a distance at which the gap between the third wiring line 71 and the fourth wiring line 72 is shortest is less than or equal to approximately 4 mm (four times or less than the wiring line width), the third wiring line 71 is less susceptible to the magnetic coupling with the fourth wiring line 72 as illustrated in FIG. 4, for example. That is, it can be said that the amount of change in a parasitic inductance is small regardless of the distance between wiring lines in a surrounding area, and it can also be said that, as compared with the case where a wiring line is not present, the amount of change in a parasitic inductance is small because the parasitic inductance is low.

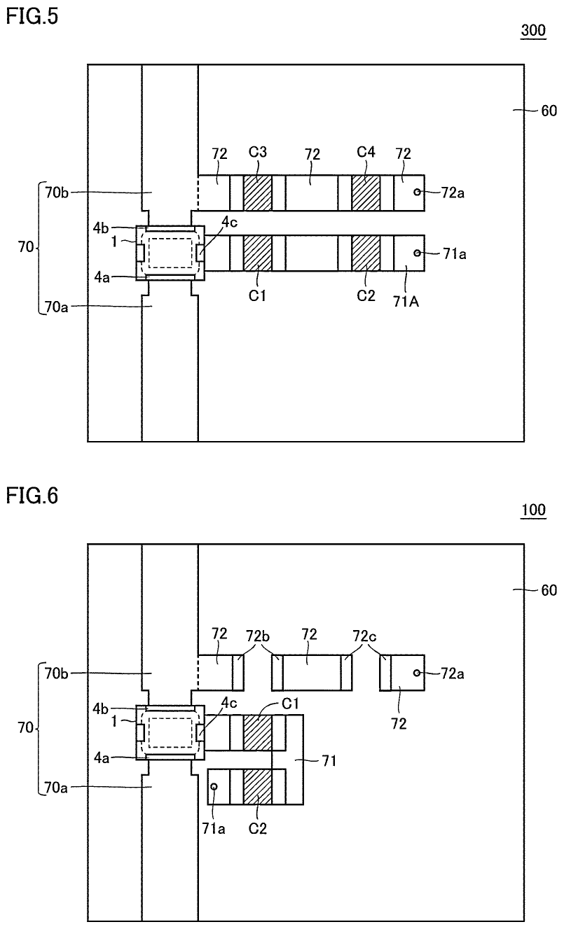

In the circuit device 100, the third wiring line 71 connected to the coil component 1 has a U-shape and is therefore less susceptible to the magnetic coupling with the fourth wiring line 72. However, there is a case where the capacitors C3 and C4 are not mounted depending on conditions where noise occurs. FIG. 6 is a plan view of the circuit device 100 according to the first example embodiment when the circuit device 100 does not include some of capacitors.

In the case where the circuit device 100 does not include the capacitors C3 and C4 as illustrated in FIG. 6, the magnetic coupling between the third wiring line 71 and the fourth wiring line 72 does not occur. However, since there is a case where the capacitors C3 and C4 are mounted depending on conditions where noise occurs, it is useful to make the third wiring line 71 U-shaped in the circuit device 100 in which the fourth wiring line 72, on which electrodes 72b and 72c provided to mount the capacitors C3 and C4 are provided, is provided on the substrate 60. That is, in the circuit device 100, there is no need to customize a coil component to cancel out the parasitic inductance of the capacitors C1 and C2 on the basis of the number of capacitors to be mounted and the arrangement of the capacitors. This leads to significant reduction in manufacturing costs.

As described above, the circuit device 100 according to the first example embodiment includes the substrate 60 on which a wiring pattern is provided and the coil component 1 mounted on the substrate 60. The coil component 1 includes the coils L1 and L2 that are magnetically coupled to each other. A first end of the coil L1 is connected to the input terminal 4a. A second end of the coil L1 and the first end of the coil L2 are connected to the intermediate terminal 4c. The second end of the coil L2 is connected to the output terminal 4b. The wiring pattern includes the first wiring line 70a connected to the input terminal 4a of the coil component 1, the second wiring line 70b connected to the output terminal 4b of the coil component 1, the third wiring line 71 on which the capacitors C1 and C2 are mounted in series and which connects the intermediate terminal 4c between the coils L1 and L2 and the ground electrode 71a, and the fourth wiring line 72 on which an electrode provided to mount the capacitors C3 and C4 in series is provided and which connects the first wiring line 70a or the second wiring line 70b to the ground electrode 72a. The circuit device 100 includes a portion where the third wiring line 71 and the fourth wiring line 72 are not parallel to each other.

Since the circuit device 100 according to the first example embodiment includes a portion where the third wiring line 71 and the fourth wiring line 72 are not parallel to each other, the effect of magnetic coupling with the fourth wiring line 72 upon the third wiring line 71 can be reduced and the change in the parasitic inductance of the capacitors C1 and C2 can be reduced or prevented.

It is desired that two or more capacitors be mounted on each of the third wiring line 71 and the fourth wiring line 72. A redundant circuit configuration can therefore be provided with which a short circuit does not occur even if one capacitor fails.

It is desired that a distance at which the gap between the third wiring line 71 and the fourth wiring line 72 is shortest be four times or less than a wiring line width of the third wiring line 71 or the fourth wiring line 72. The circuit device 100 including a portion where the third wiring line 71 and the fourth wiring line 72 are not parallel to each other can therefore effectively reduce the effect of magnetic coupling with the fourth wiring line 72 upon the third wiring line 71.

It is desired that the third wiring line 71 or the fourth wiring line 72 be U-shaped. The effect of magnetic coupling with the fourth wiring line 72 upon the third wiring line 71 can therefore be further reduced. Furthermore, a portion where capacitors are mounted can be made compact.

In the case where two or more capacitors are mounted on the U-shaped third wiring line 71, it is desired that the capacitors be mounted at respective positions where the capacitors are parallel or substantially parallel to each other. The capacitors C1 and C2 can therefore be mounted in the same direction and be easily mounted on the substrate 60.

### Modification 1-1

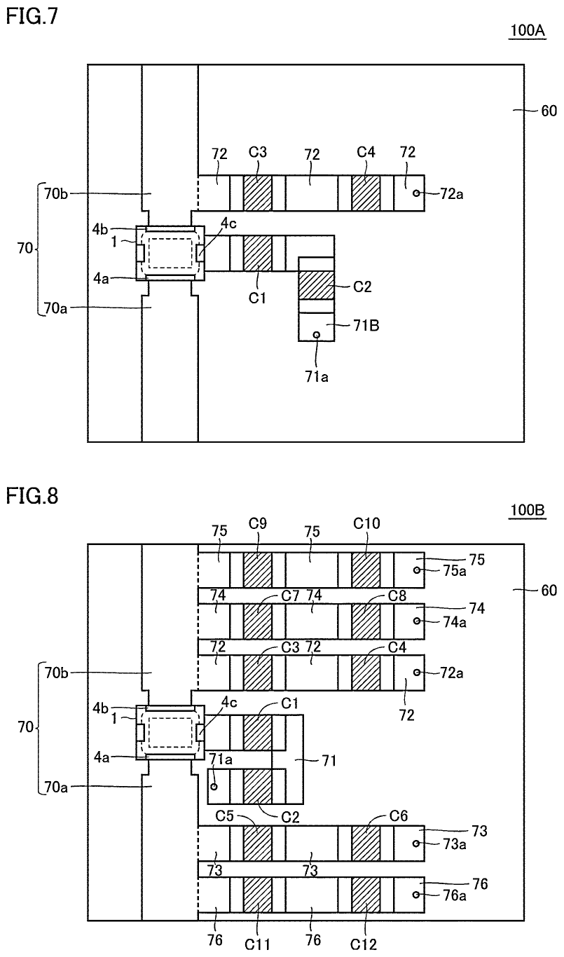

The shape of the third wiring line 71 is a U-shape as described with reference to FIG. 1, but is not limited thereto and may be, for example, an L-shape. FIG. 7 is a plan view of a circuit device 100A according to a first modification of the first example embodiment. In the circuit device 100A illustrated in FIG. 7, the same reference numeral is used to represent the same configuration as the circuit device 100 illustrated in FIG. 1 and the detailed description thereof will not be repeated.

In the circuit device 100A, a third wiring line 71B provided to mount the capacitors C1 and C2 does not have a U-shape but an L-shape bending once from the intermediate terminal 4c and reaching the ground electrode 71a. The L-shaped third wiring line 71B includes a portion not parallel to the fourth wiring line 72, and the effect of magnetic coupling with the fourth wiring line 72 upon the third wiring line 71B can therefore be reduced.

It is desired that the mounting direction of the capacitor C1 (a first capacitor) nearest to the coil component 1 of the capacitors mounted on the L-shaped third wiring line 71B and the mounting direction of the capacitor C3 (a second capacitor) nearest to the coil component 1 of the capacitors mounted on the fourth wiring line 72 be parallel or substantially parallel to each other. By making the third wiring line 71B L-shaped in the circuit device 100A, the effect of magnetic coupling with the fourth wiring line 72 upon the third wiring line 71B can be effectively reduced.

### Modification 1-2

The fourth wiring line 72 connected to the second wiring line 70b is provided in the circuit device 100 as described with reference to FIG. 1, but, for example, a fifth wiring line connected to the first wiring line 70a may be further provided in addition to the fourth wiring line 72. FIG. 8 is a plan view of a circuit device 100B according to a second modification of the first example embodiment. In the circuit device 100B illustrated in FIG. 8, the same reference numeral is used to represent the same configuration as the circuit device 100 illustrated in FIG. 1 and the detailed description thereof will not be repeated.

In the circuit device 100B, the wiring pattern of a fifth wiring line 73 is provided on the substrate 60 as a wiring line provided to mount capacitors C5 and C6. The fifth wiring line 73 electrically connects the first wiring line 70a and a ground electrode 73a with the capacitors C5 and C6 mounted thereon. As illustrated in FIG. 8, the fifth wiring line 73 linearly extends from the first wiring line 70a to the ground electrode 73a and has a linear shape. The fifth wiring line 73 exerts the effect of magnetic coupling upon the third wiring line 71 in close proximity, but the effect is reduced because of the U-shape of the third wiring line 71.

It is desired that the wiring pattern further include the fifth wiring line 73 on which an electrode provided to mount the capacitors C5 and C6 is provided, which connects the ground electrode 73a and the first wiring line 70a or the second wiring line 70b different from the wiring line connected to the fourth wiring line 72, and which includes a portion where the third wiring line 71 and the fifth wiring line 73 are not parallel to each other.

Since the circuit device 100B includes a portion where the third wiring line 71 and the fifth wiring line 73 are not parallel to each other, the effect of magnetic coupling with the fifth wiring line 73 upon the third wiring line 71 can be reduced and the change in the parasitic inductance of the capacitors C1 and C2 can be reduced or prevented.

It is desired that at least one or more capacitors be mounted at an electrode provided on the fifth wiring line 73. The fifth wiring line 73 on which a capacitor is mounted is magnetically coupled to the third wiring line 71. Accordingly, by causing the circuit device 100B to include a portion where the third wiring line 71 and the fifth wiring line 73 are not parallel to each other, the effect of magnetic coupling with the fifth wiring line 73 upon the third wiring line 71 can be effectively reduced.

It is desired that two or more capacitors be mounted on each of the third wiring line 71 and the fifth wiring line 73. A redundant circuit configuration can therefore be provided with which a short circuit does not occur even if one capacitor fails.

The multiple fourth wiring lines and the multiple fifth wiring lines may be provided in the circuit device 100B as illustrated in FIG. 8. Specifically, the multiple fourth wiring lines include a fourth wiring line 74 provided to mount capacitors C7 and C8 and a fourth wiring line 75 provided to mount capacitors C9 and C10 in addition to the fourth wiring line 72. The fourth wiring line 74 electrically connects the second wiring line 70b and a ground electrode 74a with the capacitors C7 and C8 mounted thereon. The fourth wiring line 75 electrically connects the second wiring line 70b and a ground electrode 75a with the capacitors C9 and C10 mounted thereon. The multiple fifth wiring lines include a fifth wiring line 76 provided to mount capacitors C11 and C12 in addition to the fifth wiring line 73. The fifth wiring line 76 electrically connects the first wiring line 70a and a ground electrode 76a with the capacitors C11 and C12 mounted thereon. A current path from the second wiring line 70b to the ground electrode 74a via the fourth wiring line 74 on which the capacitors C7 and C8 are mounted and a current path from the second wiring line 70b to the ground electrode 75a via the fourth wiring line 75 on which the capacitors C9 and C10 are mounted are also examples of the second current path. A current path from the first wiring line 70a to the ground electrode 73a via the fifth wiring line 73 on which the capacitors C5 and C6 are mounted and a current path from the first wiring line 70a to the ground electrode 76a via the fifth wiring line 76 on which the capacitors C11 and C12 are mounted are examples of a third current path. The paths of the fourth wiring lines 72, 74, and 75 electrically connected to the second wiring line 70b may be referred to as the third current path, and the paths of the fifth wiring lines 73 and 76 electrically connected to the first wiring line 70a may be referred to as the second current path.

### Modification 1-3

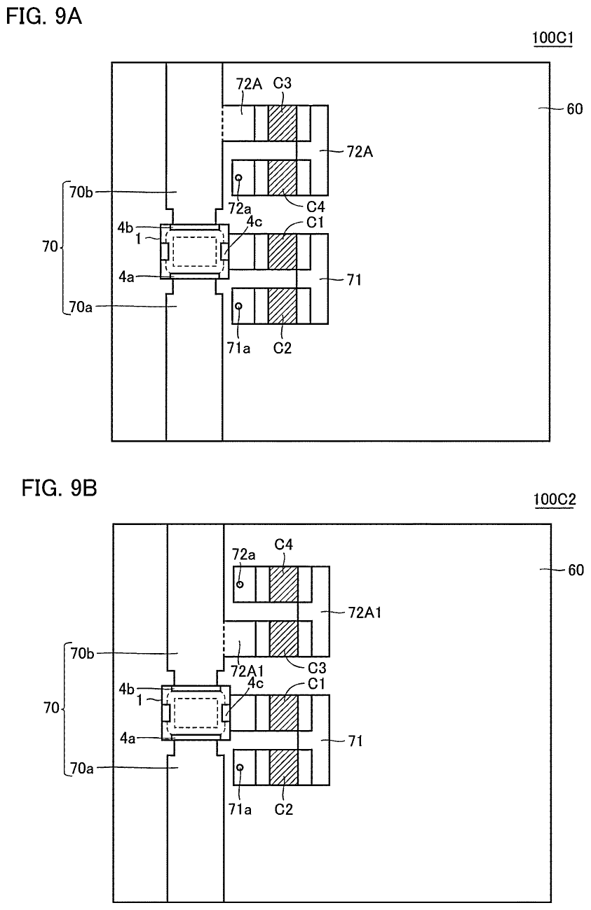

The shape of the fourth wiring line 72 is a linear shape as described with reference to FIG. 1, but is not limited thereto and may be, for example, a U-shape. FIGS. 9A and 9B are plan views of each of circuit devices 100C1 and 100C2 according to a third modification of the first example embodiment. In the circuit devices 100C1 and 100C2 illustrated in FIGS. 9A and 9B, the same reference numeral is used to represent the same configuration as the circuit device 100 illustrated in FIG. 1 and the detailed description thereof will not be repeated.

In the circuit device 100C1 illustrated in FIG. 9A, a fourth wiring line 72A provided to mount the capacitors C3 and C4 does not have a linear shape but a U-shape bending twice from the second wiring line 70b and reaching the ground electrode 72a. Both the third wiring line 71 and the fourth wiring line 72A have a U-shape. In the circuit device 100C1, the effect of magnetic coupling with the fourth wiring line 72A upon the third wiring line 71 can be further reduced.

In the circuit device 100C1, the third wiring line 71 and the fourth wiring line 72A bend in the same direction. That is, the first current path (the path of the third wiring line 71) and the second current path (the path of the fourth wiring line 72A) have the same shape and each have at least one or more bending points. Current flow directions are opposite in the portion of the third wiring line 71 where the capacitor C1 is present and the portion of the fourth wiring line 72A where the capacitor C4 is present. That is, since the directions of currents flowing through wiring lines in close proximity are opposite in the circuit device 100C1, the parasitic inductance of the capacitors C1 and C2 can be further reduced.

In the circuit device 100C2 illustrated in FIG. 9B, a fourth wiring line 72A1 provided to mount the capacitors C3 and C4 does not have a linear shape but a U-shape bending twice from the second wiring line 70b and reaching the ground electrode 72a. Both the third wiring line 71 and the fourth wiring line 72A1 have a U-shape. In the circuit device 100C2, the effect of magnetic coupling with the fourth wiring line 72A1 upon the third wiring line 71 can therefore be further reduced.

In the circuit device 100C2, the third wiring line 71 and the fourth wiring line 72A1 bend in the different directions. That is, the distance between the first current path (the path of the third wiring line 71) and the second current path (the path of the fourth wiring line 72A1) is not constant and both of them have a U-shape.

In the case where the fifth wiring line is provided in the circuit devices 100C1 and 100C2, the fifth wiring line may also have a U-shape. The circuit devices 100C1 and 100C2 can therefore further reduce the effect of magnetic coupling with the fifth wiring line upon the third wiring line 71.

### Modification 1-4

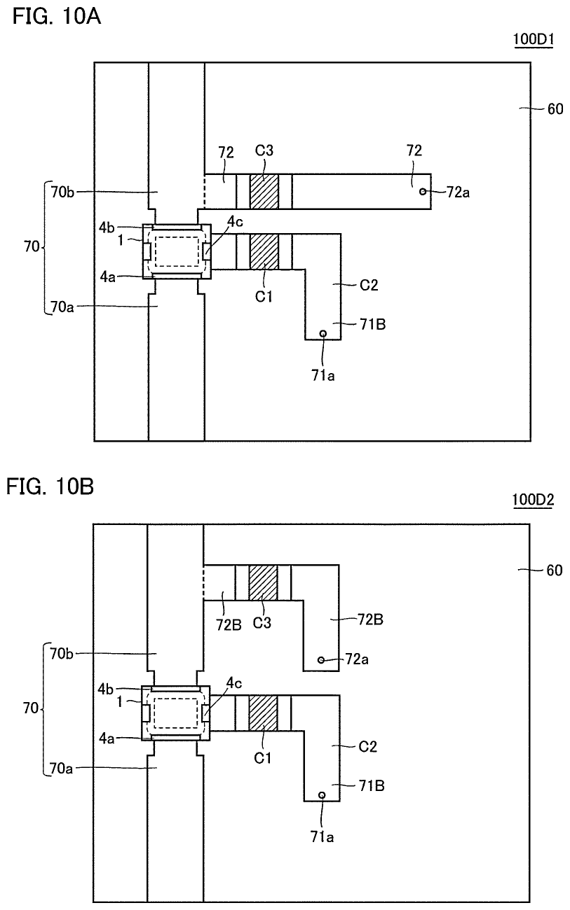

The two capacitors C1 and C2 are mounted on the L-shaped third wiring line 71B and the two capacitors C3 and C4 are mounted on the linear fourth wiring line 72 in the circuit device 100A illustrated in FIG. 7, but the number of capacitors to be mounted on a wiring line may be one. FIGS. 10A and 10B are plan views of circuit devices 100D1 and 100D2 according to a fourth modification of the first example embodiment. In the circuit devices 100D1 and 100D2 illustrated in FIGS. 10A and 10B, the same reference numeral is used to represent the same configuration as the circuit device 100 illustrated in FIG. 7 and the detailed description thereof will not be repeated.

In the circuit device 100D1 illustrated in FIG. 10A, the one capacitor C1 is mounted on the L-shaped third wiring line 71B and the one capacitor C3 is mounted on the linear fourth wiring line 72. Although not illustrated, the two capacitors C1 and C2 may be mounted on the L-shaped third wiring line 71B and the one capacitor C3 may be mounted on the linear fourth wiring line 72 in the circuit device 100D1. The one capacitor C1 may be mounted on the L-shaped third wiring line 71B and the two capacitors C3 and C4 may be mounted on the linear fourth wiring line 72 in the circuit device 100D1.

In the circuit device 100D2 illustrated in FIG. 10B, the one capacitor C1 is mounted on the L-shaped third wiring line 71B and the one capacitor C3 is mounted on an L-shaped fourth wiring line 72B having the same orientation as the third wiring line 71B. Although not illustrated, the two capacitors C1 and C2 may be mounted on the L-shaped third wiring line 71B and the one capacitor C3 may be mounted on the L-shaped fourth wiring line 72B having the same orientation as the third wiring line 71B in the circuit device 100D2. The one capacitor C1 may be mounted on the L-shaped third wiring line 71B and the two capacitors C3 and C4 may be mounted on the L-shaped fourth wiring line 72B having the same orientation as the third wiring line 71B in the circuit device 100D2. In the circuit device 100D2, the L-shaped third wiring line 71B and the L-shaped fourth wiring line 72B may have different orientations.

In the case where the fifth wiring line is provided in the circuit devices 100D1 and 100D2, the fifth wiring line may also have a L-shape. The circuit devices 100D1 and 100D2 can therefore further reduce the effect of magnetic coupling with the fifth wiring line upon the third wiring line 71.

### Second Example Embodiment

The third wiring line 71 connected to the intermediate terminal 4c bends in the circuit device 100 according to the first example embodiment, and the circuit device 100 therefore includes a portion not parallel to the fourth wiring line 72. The third wiring line does not bend and the fourth wiring line bends in a circuit device according to the second example embodiment, and the circuit device therefore includes a portion where the fourth wiring line is not parallel to the third wiring line. FIG. 11 is a plan view of a circuit device 200 according to the second example embodiment. In the circuit device 200 illustrated in FIG. 11, the same reference numeral is used to represent the same configuration as the circuit device 100 illustrated in FIG. 1 and the detailed description thereof will not be repeated.

In the circuit device 200, the wiring pattern of the power supply line 70 is provided on the surface of the substrate 60 and the coil component 1 is mounted in series to the power supply line 70. The power supply line 70 includes the first wiring line 70a connected to the input terminal 4a of the coil component 1 and the second wiring line 70b connected to the output terminal 4b of the coil component 1.

In the circuit device 200, the two capacitors C1 and C2 are connected in series to the intermediate terminal 4c of the coil component 1. The wiring pattern of the third wiring line 71A is provided on the substrate 60 as a wiring line provided to mount the capacitors C1 and C2. The third wiring line 71A electrically connects the intermediate terminal 4c between the two coils included in the coil component 1 and the ground electrode 71a with the capacitors C1 and C2 mounted thereon. In the circuit device 200, the two capacitors C3 and C4 are connected in series to the second wiring line 70b near the coil component 1. The wiring pattern of the fourth wiring line 72A is provided on the substrate 60 as a wiring line provided to mount the capacitors C3 and C4. The fourth wiring line 72A electrically connects the second wiring line 70b and the ground electrode 72a with the capacitors C3 and C4 mounted thereon. The fourth wiring line 72A may be provided on the first wiring line 70a instead of the second wiring line 70b.

As illustrated in FIG. 11, the third wiring line 71A linearly extends from the intermediate terminal 4c to the ground electrode 71a and has a linear shape. However, the fourth wiring line 72A has a U-shape bending twice from the second wiring line 70b and reaching the ground electrode 72a. Thus, by giving the fourth wiring line 72A a U-shape instead of a linear shape that is the same as the shape of the third wiring line 71A, the effect of magnetic coupling with the fourth wiring line 72A upon the third wiring line 71A can be reduced and the change in the parasitic inductance of the capacitors C1 and C2 can be reduced or prevented.

The third wiring line 71A has a linear shape and the fourth wiring line 72A has a U-shape in the circuit device 200 according to the second example embodiment as described above, and the circuit device 200 therefore includes a portion where the third wiring line 71A and the fourth wiring line 72A are not parallel to each other.

Since the circuit device 200 according to the second example embodiment includes the portion where the third wiring line 71A and the fourth wiring line 72A are not parallel to each other, the effect of magnetic coupling with the fourth wiring line 72A upon the third wiring line 71A can be reduced and the change in the parasitic inductance of the capacitors C1 and C2 can be reduced or prevented.

It is desired that at least one or more capacitors be mounted at an electrode provided on the fourth wiring line 72A. It is also desired that two or more capacitors be mounted on each of the third wiring line 71A and the fourth wiring line 72A.

### Modification 2-1

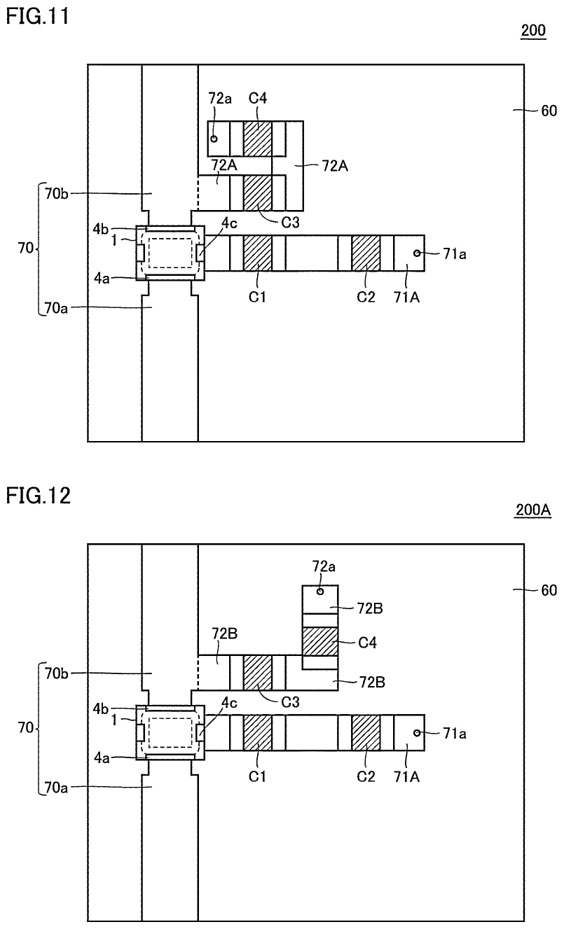

The shape of the fourth wiring line 72A is a U-shape as described with reference to FIG. 11, but is not limited thereto and may be, for example, an L-shape. FIG. 12 is a plan view of a circuit device 200A according to a first modification of the second example embodiment. In the circuit device 200A illustrated in FIG. 12, the same reference numeral is used to represent the same configuration as the circuit device 200 illustrated in FIG. 11 and the detailed description thereof will not be repeated.

In the circuit device 200A, the fourth wiring line 72B provided to mount the capacitors C3 and C4 does not have a U-shape but an L-shape bending once from the second wiring line 70b and reaching the ground electrode 72a. The L-shaped fourth wiring line 72B includes a portion not parallel to the third wiring line 71A, and the effect of magnetic coupling with the fourth wiring line 72B upon the third wiring line 71A can therefore be reduced.

It is desired that the mounting direction of the capacitor C3 nearest to the coil component 1 of the capacitors mounted on the L-shaped fourth wiring line 72B and the mounting direction of the capacitor C1 nearest to the coil component 1 of the capacitors mounted on the third wiring line 71A be parallel or substantially parallel to each other. By making the fourth wiring line 72B L-shaped in the circuit device 200A, the effect of magnetic coupling with the fourth wiring line 72B upon the third wiring line 71A can be effectively reduced.

### Modification 2-2

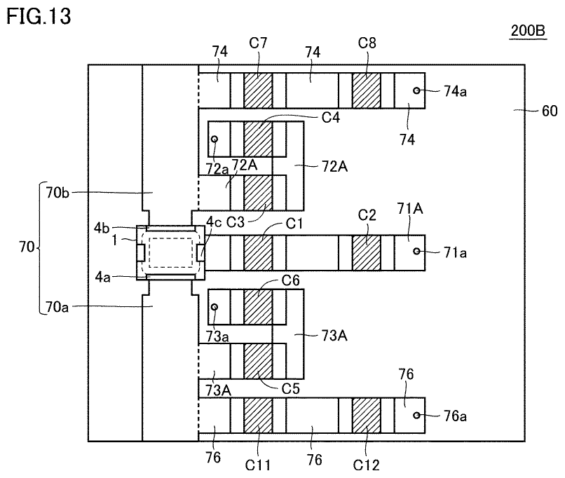

The fourth wiring line 72A connected to the second wiring line 70b is provided in the circuit device 200 as described with reference to FIG. 11, but, for example, a fifth wiring line connected to the first wiring line 70a may be further provided in addition to the fourth wiring line 72A. FIG. 13 is a plan view of a circuit device 200B according to a second modification of the second example embodiment. In the circuit device 200B illustrated in FIG. 13, the same reference numeral is used to represent the same configuration as the circuit device 200 illustrated in FIG. 11 and the detailed description thereof will not be repeated.

In the circuit device 200B, the wiring pattern of a fifth wiring line 73A is provided on the substrate 60 as a wiring line provided to mount capacitors C5 and C6. The fifth wiring line 73A electrically connects the first wiring line 70a and the ground electrode 73a with the capacitors C5 and C6 mounted thereon. As illustrated in FIG. 13, the fifth wiring line 73A has a U-shape bending twice from the first wiring line 70a and reaching the ground electrode 73a. The fifth wiring line 73A exerts the effect of magnetic coupling upon the third wiring line 71A in close proximity, but the effect can be reduced because of the U-shape of the third wiring line 73A.

It is desired that the wiring pattern further include the fifth wiring line 73A on which an electrode provided to mount the capacitors C5 and C6 is provided, which connects the ground electrode 73a and the first wiring line 70a or the second wiring line 70b different from the wiring line connected to the fourth wiring line 72A, and which includes a portion where the third wiring line 71A and the fifth wiring line 73A are not parallel to each other.

The fourth wiring line 72A and the fifth wiring line 73A bend in the same direction in FIG. 13, but do not necessarily have to bend in the same direction. For example, the fourth wiring line 72A may bend such that the capacitor C4 is located on the first wiring line 70a side.

Since the circuit device 200B has the portion where the third wiring line 71A and the fifth wiring line 73A are not parallel to each other, the effect of magnetic coupling with the fifth wiring line 73A upon the third wiring line 71A can be reduced and the change in the parasitic inductance of the capacitors C1 and C2 can be reduced or prevented.

It is desired that at least one or more capacitors be mounted at an electrode provided on the fifth wiring line 73A. The fifth wiring line 73A on which a capacitor is mounted is magnetically coupled to the third wiring line 71A. Accordingly, by causing the circuit device 200B to include a portion where the third wiring line 71A and the fifth wiring line 73A are not parallel to each other, the effect of magnetic coupling with the fifth wiring line 73A upon the third wiring line 71A can be effectively reduced.

It is desired that two or more capacitors be mounted on each of the third wiring line 71A and the fifth wiring line 73A. A redundant circuit configuration can therefore be provided with which a short circuit does not occur even if one capacitor fails.

The multiple fourth wiring lines and the multiple fifth wiring lines may be provided in the circuit device 200B as illustrated in FIG. 13. Specifically, the multiple fourth wiring lines include the fourth wiring line 74 provided to mount capacitors C7 and C8 in addition to the fourth wiring line 72A. The fourth wiring line 74 electrically connects the second wiring line 70b and the ground electrode 74a with the capacitors C7 and C8 mounted thereon. The multiple fifth wiring lines include the fifth wiring line 76 provided to mount capacitors C11 and C12 in addition to the fifth wiring line 73A. The fifth wiring line 76 electrically connects the first wiring line 70a and the ground electrode 76a with the capacitors C11 and C12 mounted thereon.

The shape of the fifth wiring line 73A is a U-shape as described with reference to FIG. 13, but is not limited thereto and may be, for example, an L-shape.

In the circuit devices 100, 100A to 100D1, 100D2, 200, and 200A to 200B, it is desired that at least one of the first current path (the path of the third wiring line 71) connected to the coil component 1 or the second current path (the path of the fifth wiring line 73 or the fourth wiring line 72) connected to the first wiring line 70a or the second wiring line 70b bend in the middle for reduction or prevention of the change in the parasitic inductance of a capacitor as described above. In particular, since a capacitor is mounted on the first current path (the path of the third wiring line 71) without fail, it is desired that the first current path (the path of the third wiring line 71) bend in the middle (the U-shaped third wiring line 71 and the L-shaped third wiring line 71B).

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit device comprising:
a substrate on which a wiring pattern is located; and
a coil component mounted on the substrate; wherein
the coil component includes a first coil and a second coil that are magnetically coupled to each other;
a first end of the first coil is connected to an input terminal, a second end of the first coil and a first end of the second coil are connected to an intermediate terminal, and a second end of the second coil is connected to an output terminal;
the wiring pattern includes:
a first wiring line connected to the input terminal;
a second wiring line connected to the output terminal;
a third wiring line on which at least one or more capacitors are mounted in series and which electrically connects the intermediate terminal and a ground electrode; and
a fourth wiring line on which an electrode provided to mount at least one or more capacitors in series is provided and which electrically connects the first wiring line or the second wiring line to a ground electrode; and
a distance between a first current path on which a current flows from the coil component to a ground electrode via the third wiring line and a second current path on which a current flows from the first wiring line or the second wiring line to a ground electrode via the fourth wiring line on which a capacitor is mounted at an electrode is not constant.

2. The circuit device according to claim 1, wherein the first current path connected to the coil component and the second current path connected to the first wiring line or the second wiring line are parallel or substantially parallel to each other, and a path bends in a middle of the first current path or the second current path.

3. The circuit device according to claim 2, wherein a path bends at right angles in a middle of the first current path or the second current path.

4. The circuit device according to claim 1, wherein at least one or more capacitors are mounted at an electrode provided on the fourth wiring line.

5. The circuit device according to claim 4, wherein two or more capacitors are mounted on each of the third wiring line and the fourth wiring line.

6. The circuit device according to claim 4, wherein a mounting direction of a first capacitor nearest to the coil component of capacitors mounted on the third wiring line and a mounting direction of a second capacitor nearest to the coil component of capacitors mounted on the fourth wiring line are parallel or substantially parallel to each other.

7. The circuit device according to claim 1, wherein a distance at which a gap between the third wiring line and the fourth wiring line is shortest is four times or less than a wiring line width of the third wiring line or the fourth wiring line.

8. The circuit device according to claim 1, wherein the first current path or the second current path includes paths where current flow directions are opposite.

9. The circuit device according to claim 8, wherein, when two or more capacitors are mounted on the third wiring line or the fourth wiring line, the capacitors are mounted at respective positions where the capacitors are parallel or substantially parallel to each other and directions of currents flowing through the capacitors are opposite.

10. The circuit device according to claim 1, wherein the circuit device is an EMI rejection filter.

11. The circuit device according to claim 1, wherein the circuit device is a third-order T-type LC filter circuit or a fifth-order T-type LC filter circuit or a T-type LC filter circuit of a higher order than a third-order or fifth-order.

12. A circuit device comprising:
a substrate on which a wiring pattern is provided; and
a coil component mounted on the substrate; wherein
the coil component includes a first coil and a second coil that are magnetically coupled to each other;
a first end of the first coil is connected to an input terminal, a second end of the first coil and a first end of the second coil are connected to an intermediate terminal, and a second end of the second coil is connected to an output terminal;
the wiring pattern includes:
a first wiring line connected to the input terminal;
a second wiring line connected to the output terminal;
a third wiring line on which at least one or more capacitors are connected in series and which electrically connects the intermediate terminal and a ground electrode; and
a fourth wiring line on which an electrode provided to mount at least one or more capacitors in series is provided and which electrically connects the first wiring line or the second wiring line to a ground electrode; and
a first current path on which a current flows from the coil component to a ground electrode via the third wiring line and a second current path on which a current flows from the first wiring line or the second wiring line to a ground electrode via the fourth wiring line on which a capacitor is mounted at an electrode have a same shape and each includes at least one or more bending points.

13. The circuit device according to claim 12, wherein directions of currents flowing through adjacent paths on the first current path and the second current path are opposite.

14. The circuit device according to claim 12, wherein
the wiring pattern further includes a fifth wiring line on which an electrode provided to mount at least one or more capacitors is provided and which electrically connects the first wiring line or the second wiring line different from a wiring line connected to the fourth wiring line to a ground electrode; and
a distance between the first current path and a third current path on which a current flows from the first wiring line or the second wiring line to a ground electrode via the fifth wiring line on which a capacitor is mounted at an electrode is not constant.

15. The circuit device according to claim 14, wherein at least one or more capacitors are mounted at an electrode provided on the fifth wiring line.

16. The circuit device according to claim 15, wherein two or more capacitors are mounted on each of the third wiring line and the fifth wiring line.

17. The circuit device according to claim 15, wherein the third current path includes paths where current flow directions are opposite.

18. The circuit device according to claim 12, wherein the circuit device is an EMI rejection filter.

19. The circuit device according to claim 12, wherein the circuit device is a third-order T-type LC filter circuit or a fifth-order T-type LC filter circuit or a T-type LC filter circuit of a higher order than a third-order or fifth-order.
